(19) United States
(12) Patent Application Publication
(10) Pub. No.: US 2026/0282299 A1
(43) Pub. Date: Sep. 17, 2026

(54) HEAT DISSIPATION ASSEMBLY, BASE PLATE AND METHODS FOR THE USE AND ASSEMBLY THEREOF

(71) Applicant: DSP Solutions Inc., Oxnard, CA (US)

(72) Inventors: Anthony T. D’Amore, Newbury Park, CA (US); Juan Rodriguez, Moorpark, CA (US)

(73) Assignee: DSP Solutions Inc., Oxnard, CA (US)

(21) Appl. No.: 19/078,556

(22) Filed: Mar. 13, 2025

(51) Int. Cl. H05K 7/20

(52) U.S. Cl. CPC H05K 7/209; H05K 7/205

(57) ABSTRACT

A heat dissipation assembly includes a heat sink having an exterior surface and an interior air flow passageway defining a longitudinal axis. The air flow passageway has an inlet and an outlet. A fan creates an air flow from the inlet to the outlet through the interior air flow passageway. A plurality of laterally spaced heat producing electronic component abut the exterior surface of the heat sink. A base plate includes a base portion and an air guide extending orthogonally from the base portion along the longitudinal axis. At least a portion of the air guide extends through the outlet and is disposed in the interior air flow passageway of the heat sink. An electronic assembly, such as an amplifier, a base plate and a method of dissipating heat are also disclosed.

### FIELD OF THE INVENTION

The present application relates generally to a heat dissipation assembly, including a base plate, for example as incorporated into an electronic device, such as an amplifier, and to the methods for the use and assembly thereof.

### BACKGROUND

Electronic devices, such as amplifiers, may be configured with heat producing electronic components, including for example and without limitation transistors or other semiconductor components. While heat sinks may be incorporated into such assemblies to help cool the heat producing components, such cooling is typically performed in series, such that downstream components may experience less cooling and be subjected to higher temperatures that may shorten the life expectancy of those components. The arrangement and capabilities of the heat sink and heat producing components often contributes to the need for a larger, bulky housing to accommodate those components. Moreover, due to the arrangement of the components, the housing may be warm or hot to the touch. While a fan may be used to generate an air flow over or around the heat sink to facilitate cooling, such fans, and the turbulent air flow created thereby, often generate excessive noise.

### SUMMARY

The present invention is defined by the following claims, and nothing in this section should be considered to be a limitation on those claims.

In one aspect, one embodiment of a heat dissipation assembly includes a heat sink having an exterior surface and an interior air flow passageway defining a longitudinal axis. The air flow passageway has an inlet and an outlet. A fan creates an air flow from the inlet to the outlet through the interior air flow passageway. A plurality of laterally spaced heat producing electronic component abut the exterior surface of the heat sink. A base plate includes a base portion and an air guide extending orthogonally from the base portion along the longitudinal axis. At least a portion of the air guide extends through the outlet and is disposed in the interior air flow passageway of the heat sink.

In another aspect, one embodiment of an amplifier includes a housing enclosing the heat dissipation assembly, including without limitation the fan, heat sink and base plate.

In another aspect, one embodiment of a base plate is configured to guide air exiting a heat sink. The base plate includes a planar base portion having a peripheral edge, a first side and an opposite second side. An air guide extends orthogonally from the first side of the base portion. The air guide has a rounded cone shape surface.

In yet another aspect, one embodiment of method of dissipating heat from a plurality of heat producing electronic components includes transferring heat from the plurality of heat producing electronic components to an exterior surface of a heat sink, wherein the plurality of heat producing electronic components are arranged in parallel relative to a longitudinal axis of the heat sink, blowing air through an inlet of an interior passageway of the heat sink to an outlet, wherein the interior passageway extends along the longitudinal axis of the heat sink, directing the air along a surface of an air guide extending through the outlet into the interior passageway, and directing the air laterally along a surface of a base plate to an ambient environment.

Other methods of using and assembling the heat dissipation assembly are also provided.

The various embodiments of the heat dissipation assembly, base plate, electronic devices such as an amplifier, and methods provide significant advantages over other heat dissipation assemblies, base plates, electronic devices and methods for the manufacture, use and assembly thereof. For example, and without limitation, the heat producing electronic components may be arranged in parallel along the heat sink, such that those components are cooled evenly and are maintained at similar temperatures. The air guide, and base plate, reduce the turbulence of the air flow and any associated fan noise. The compact arrangement of the base plate, with the air guide disposed in the heat sink, allows for a compact arrangement resulting in a smaller size/footprint of the housing and electronic device without sacrificing performance. The housing and electronic device are cool to the touch, since the heat producing elements are disposed internally and not in contact with any external components.

The foregoing paragraphs have been provided by way of general introduction and are not intended to limit the scope of the following claims. The various preferred embodiments, together with further advantages, will be best understood by reference to the following detailed description taken in conjunction with the accompanying drawings.

### BRIEF DESCRIPTION OF THE DRAWINGS

FIG. 1 is a perspective view of one embodiment of an amplifier.

FIG. 2 is a top perspective view of one embodiment of a heat dissipation assembly.

FIG. 3 is a bottom perspective view of one embodiment of the heat dissipation assembly shown in FIG. 2.

FIG. 4 is a top partial, exploded view of the heat dissipation assembly shown in FIG. 2, excluding the base plate.

FIG. 5 is a bottom partial, exploded view of the heat dissipation assembly shown in FIG. 2, excluding the base plate.

FIG. 6 is a perspective view of one embodiment of a heat sink.

FIG. 7 is a bottom view of the heat sink shown in FIG. 6.

FIG. 8A and B are top partial, exploded views of one embodiment of the heat dissipation assembly, excluding the circuit board in FIG. 8A and the circuit board, fan and heat producing electronic components in FIG. 8B.

FIG. 9 is an exploded view of one embodiment of a heat sink and a base plate.

FIG. 10 is a top, perspective view of one embodiment of a base plate.

FIG. 11 is a side view of one embodiment of a base plate and a circuit board.

FIG. 12 is a partial, perspective view of the base plate and circuit board shown in FIG. 11.

FIG. 13 is a top view of the base plate and circuit board shown in FIG. 11.

FIG. 14 is a side view of one embodiment of a base plate and a circuit board.

FIG. 15 is a top view of the base plate and circuit board shown in FIG. 14.

FIG. 16 is a perspective view of one embodiment of an amplifier.

FIG. 17 is a top, exploded view of one embodiment of the heat dissipation assembly.

FIG. 18 is a perspective view of the heat dissipation assembly shown in FIG. 17.

FIG. 19 is a bottom view of an alternative embodiment of a heat sink.

FIG. 20 is a perspective view of an alternative embodiment of a base plate.

### DETAILED DESCRIPTION OF THE PRESENTLY PREFERRED EMBODIMENTS

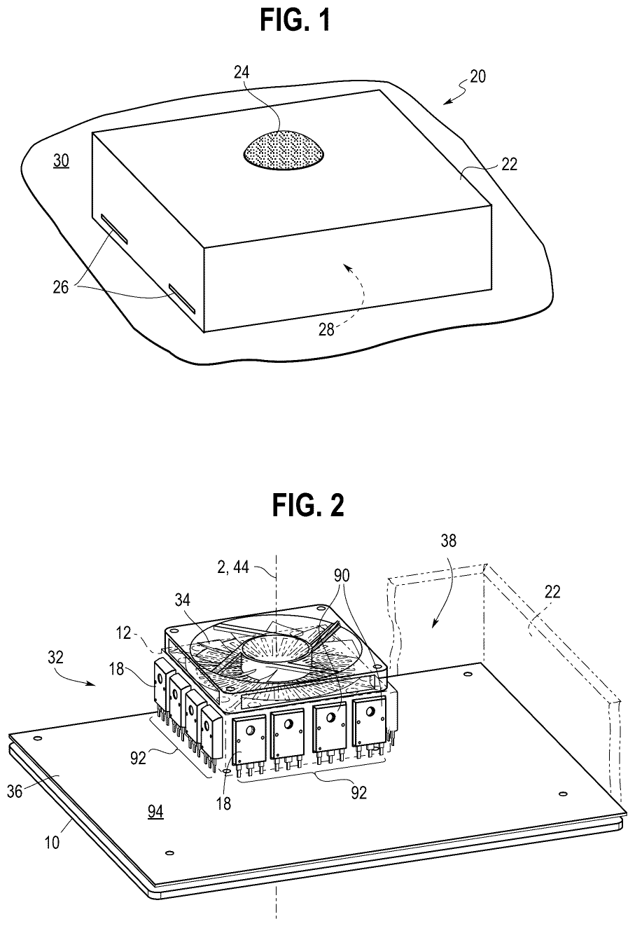

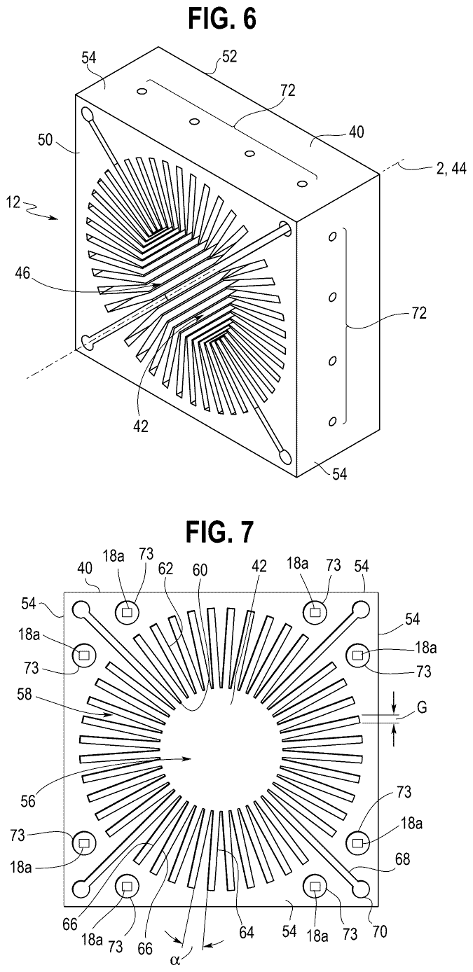

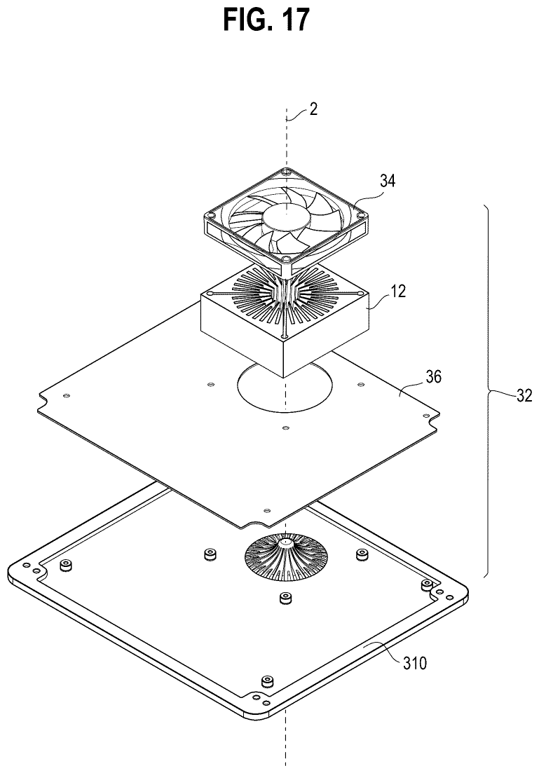

It should be understood that the term “plurality,” as used herein, means two or more. As shown in FIGS. 2, 4, 6, 8A and B, 9, 17 and 20, the term “longitudinal,” as used herein, means of or relating to a length or lengthwise direction 2, for example a direction running from a top to bottom of a heat sink 12 and/or air guide 14, 314, and may be defined as a Z axis. The term “lateral,” as used herein, means situated on, directed toward or running in a side-to-side direction 4 of a base plate 10, 310, and may be referred to as the X axis. A third Y axis is situated on, directed toward or running in a front-to-back direction 6 of the base plate 10. The X/Y axes, or directions 4, 6, may lie in and define a planar base portion 110, 410 of the base plate 10, 310 while the Z axis (longitudinal direction) extends orthogonal to a planar base portion 110, 410 of the base plate. The term “coupled” means connected to or engaged with whether directly or indirectly, for example with an intervening member, and does not require the engagement to be fixed or permanent, although it may be fixed or permanent. The term “fixed” means not moveable. The terms “first,” “second,” and so on, as used herein, are not meant to be assigned to a particular component or feature so designated, but rather are simply referring to such components and features in the numerical order as addressed, meaning that a component or feature designated as “first” may later be a “second” such component or feature, depending on the order in which it is referred. It should also be understood that designation of “first” and “second” does not necessarily mean that the two components, features or values so designated are different, meaning for example a first direction may be the same as a second direction, with each simply being applicable to different components or features. The terms “upper,” “lower,” “rear,” “front,” “fore,” “aft,” “vertical,” “horizontal,” and variations or derivatives thereof, refer to the orientations of the exemplary electronic assembly shown in FIGS. 1, 2, 16 and 17 from the perspective of a person facing and using the assembly. The phrase “electronic device,” or assembly, refers to any device incorporating electronic components, and includes without limitation, computers, audio components, amplifiers, televisions, appliances (e.g., refrigerators/freezers/coolers, dishwashers, microwave ovens, washing/drying machines), etc. The electronic device includes or incorporates heat producing electronic components 18, such as transistors and other semiconductor components.

Referring to FIGS. 1 and 16, an electronic device 20, 320 is shown as including a housing 22, 322. The housing 22, 322 may have a cuboid shape, or may be an irregular or circular shape. The housing defines an interior cavity 28. The housing 22, 322 may be made of metal, plastic, or other suitable structural material. In one embodiment, the electronic device is an amplifier. The housing 22, 322 may have one or more intake vents 24 and/or exhaust vents 26 communicating (i.e., fluidly) between the ambient environment 30 surrounding the housing 22, 322 and the interior cavity 28.

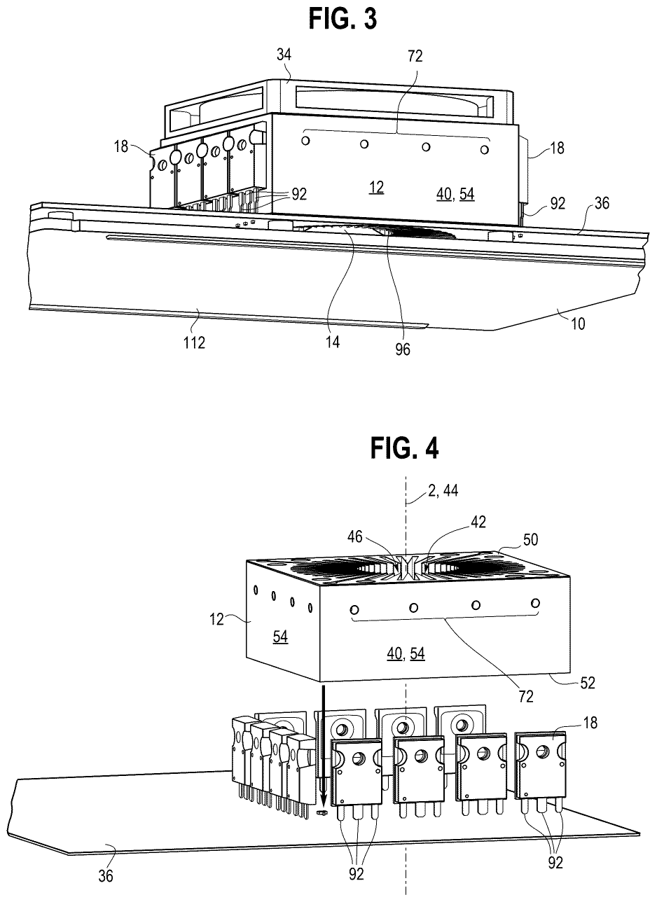

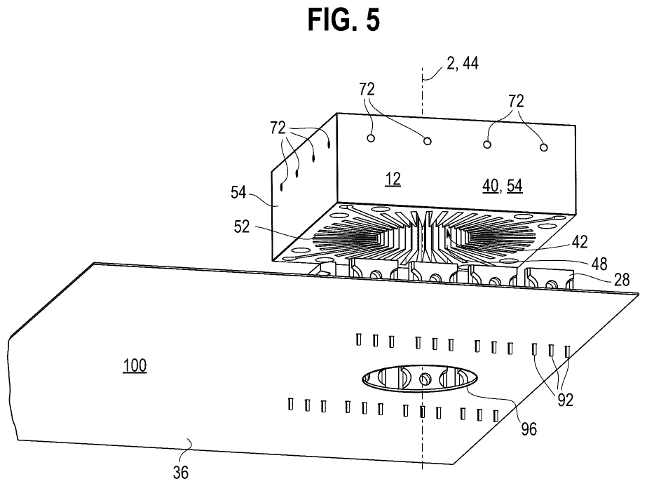

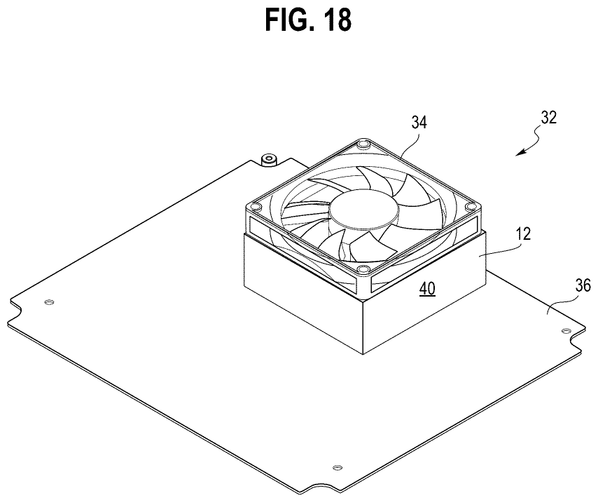

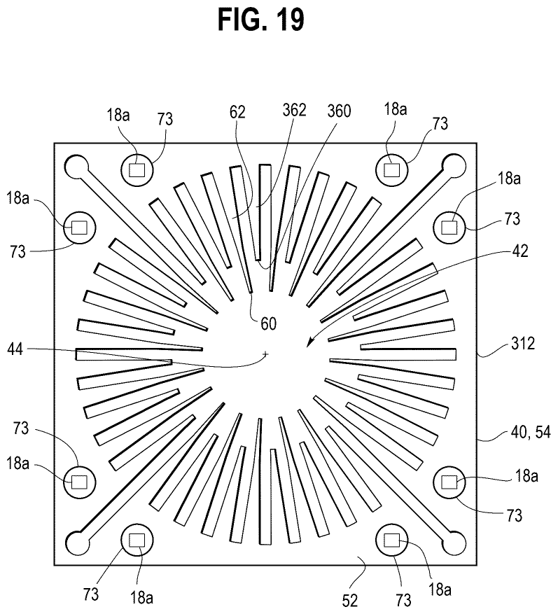

Referring to FIGS. 2-10, and 17-19, the electronic device 20, for example an amplifier, includes a heat dissipation assembly 32 disposed in the interior cavity 28 of the housing 22, 322. The heat dissipation assembly 32 may include one or more of a fan 34, the heat sink 12, 312, a circuit board 36, one or more heat producing electronic components 18 and the base plate 10, 310, all disposed in the interior cavity 28 of the housing 22, 322. In one embodiment, the heat sink 12, 312 includes an exterior surface 40 and an interior air flow passageway 42 defining a longitudinal axis 44. The air flow passageway 42 has an inlet 46 and an outlet 48. The inlet may be positioned adjacent to, or below, the intake vent 24 of the housing 22, 322 in one embodiment. The heat sink 12, 312 may have a prism shape, with an upper face 50 and a lower face 52, preferably but not necessarily parallel to each other, and a plurality of flat sides 54 extending longitudinally between and connecting the faces 50, 52. The sides 54 define the exterior surface 40 of the heat sink 12, 312. In one embodiment, the exterior surface 40, or sides 54, are flat such that the heat transfer area, defined by the sides in contact with the heat producing electronic components 18, is maximized. The prism shape of the heat sink may be configured as a triangular prism (three sides), cuboid prism (four sides), pentagonal prism (five sides), hexagonal prism (six sides), heptagonal prism (seven sides), octagonal prism (8 sides), and so on, with n=number of sides, where n≥3. It should be understood that the heat sink 12 may be configured as a cylinder having a single, circumferential side surface.

The air flow passageway 42 may include a central, cylindrical passageway 56 defined by the free ends 60, 360 of a plurality of fins 62, 362 formed in a body of the heat sink 12 and extending radially inwardly toward the longitudinal axis 44. In the embodiment of FIG. 19, the fins 62 extend radially inwardly toward the axis 2 a greater amount than the fins 362. In one embodiment, the fins 62, 362 alternate. The fins 62, 362 are circumferentially spaced around the longitudinal axis 44. The air flow passageway 42 further includes the spaces 64 defined between adjacent, circumferentially spaced fins 62. The width (G) of the space 64 between fins may be between 1 mm and 3 mm in one embodiment. In one embodiment, the opposite sides 66 of each fin 63 define an acute angle (α) of between 5 and 10 degrees, and are 8 degrees in one embodiment. The air flow passageway 42 may also include elongated slots 68 extending radially from each of the corners, with an end of the slot formed as a circular opening 70. Each side 54 of the exterior surface 40 includes one or more mounting features 72, shown as openings, which may be threaded. The lower, exterior face 52, or surface, may also include one or more mounting features to receive one or more abutted heat producing electronic components. For example, as seen in the embodiments of FIGS. 7 and 19, a plurality of mounting features may be formed as pockets or recesses 73 configured to receive and encapsulate additional heat producing electronic components 18a (e.g., smaller transistors and/or thermal sensors). Advantageously, the mounting features positioned on the lower, exterior face 52 do not occupy any space on the sides 54 of the heat sink 12, thereby maximizing space on the side 54 for larger heat producing components 18. The heat sink 12 may be made of a heat conductive material, such as metal, including for example aluminum.

The fan 34 is coupled to the upper face 50 of the heat sink, for example with one or more fasteners, which may include screws, interference posts, tabs or other suitable connectors. The fan 34, which may be an electric fan, creates an air flow 80 when actuated. The air flow is transmitted from the inlet 46 to the outlet 48 through the interior air flow passageway 42. The fan may draw air from the ambient environment 30 through the intake vent 24 of the housing. In this embodiment, the fan 34 produces a positive air flow (e.g., positive pressure) in the air flow passageway, while in other embodiments, the fan may be located or positioned relative to the heat sink to produce a negative pressure, or vacuum, drawing air through the air flow passageway 42.

A plurality of laterally spaced heat producing electronic components 18 abut, and may be connected to, the exterior surface 40, and the sides 54 or lower face in particular, of the heat sink 12. In one embodiment, as shown in FIGS. 2-4 and 8A and B, the heat producing components 18 are configured as a plurality of semiconductor transistors (shows as four), which abut and are connected to each side 54 of the heat sink 12. The heat producing components 18 are preferably in contact with the exterior surface 40 so as to allow for conductive heat transfer from the heat producing components 18 to the heat sink 12. The air flow 80 through the air flow passageway 42 thereafter dissipates the heat from the heat sink 12 by way of convection, and to a smaller degree radiation. The heat producing components 18 may be coupled to the heat sink 12 with a mounting feature 90, for example a fastener, that engages a corresponding one of the mounting features 72 on the side 54 of the heat sink 12. The heat producing component 18, e.g., transistor, may include one or more contacts 92, disclosed for example and without limitation as three contacts configured for example as a base, collector and emitter contact, which are connected to the circuit board 36. The plurality of laterally spaced heat producing electronic components 18 abutting the exterior surface 40 of the heat sink 12 are arranged in parallel around the longitudinal axis 44, meaning the heat producing electronic components 18 experience the same level of heat dissipation from the heat sink 18.

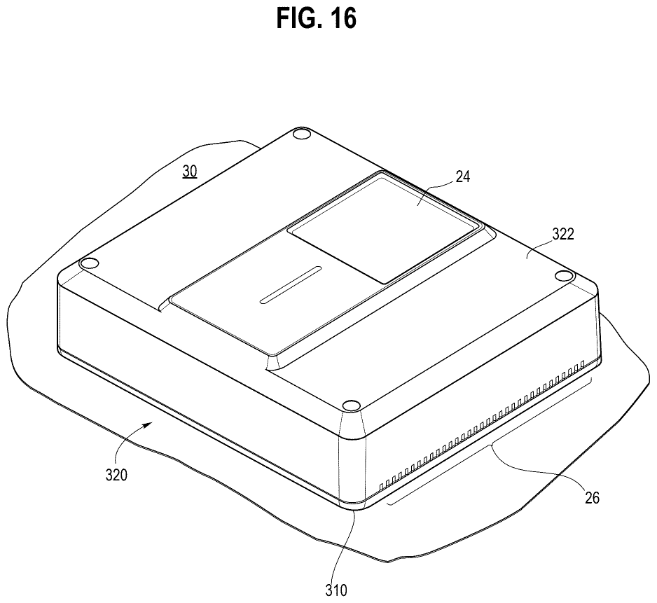

The circuit board 36 may be configured as a printed circuit board (PCB). The PCB may be formed as a planar laminate structure 94 of conductive and insulating layers, with various electronic components, such as the heat producing components 18, electrically connected to conductive pads on the PCB, or by inserting the contacts through holes in the PCB. The PCB may be single-sided (one copper layer), double-sided (two copper layers on both sides of one substrate layer), or multi-layered (outer and inner layers of copper, alternating with layers of substrate). As shown in FIGS. 13 and 15, the PCB has an opening 96 formed therein that is aligned with the air flow passageway 42. The circuit board 36 is preferably planar and has an upper and lower side 98, 100, with the upper side 100 facing the heat sink 12 and from which the heat producing components 18 extend. The circuit board 36 is vertically offset from, and attached to, the underlying base plate 10. Spacers 102 may be disposed between the lower side 98 of the circuit board 36 and an upper side 104 of the base plate 10 so as to define and maintain a space 106 therebetween.

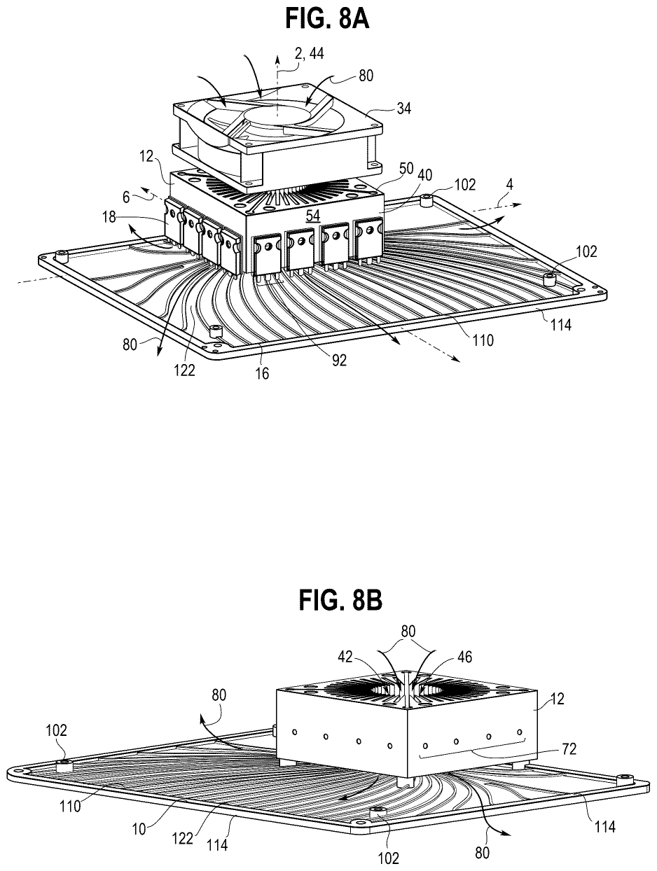

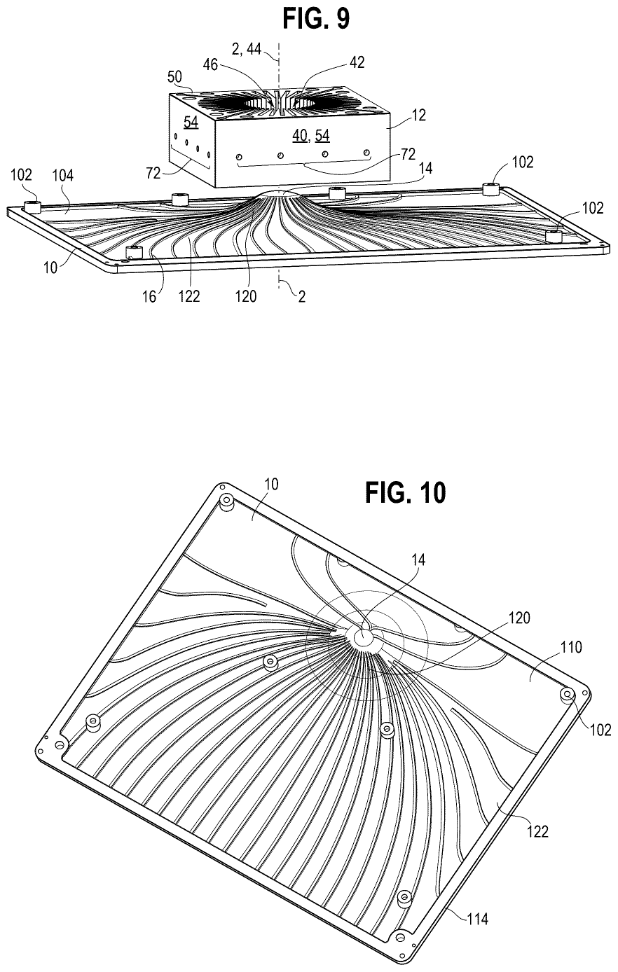

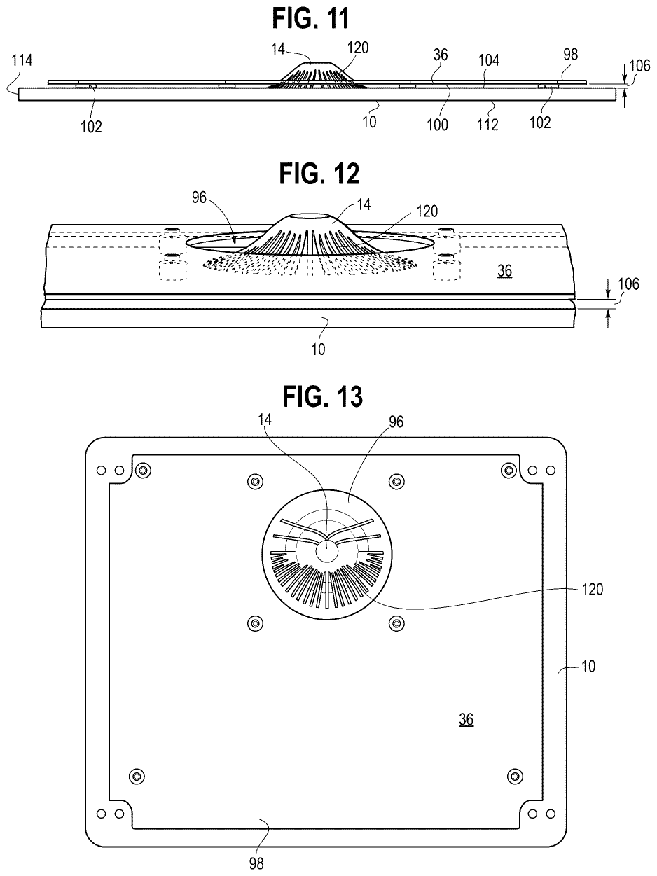

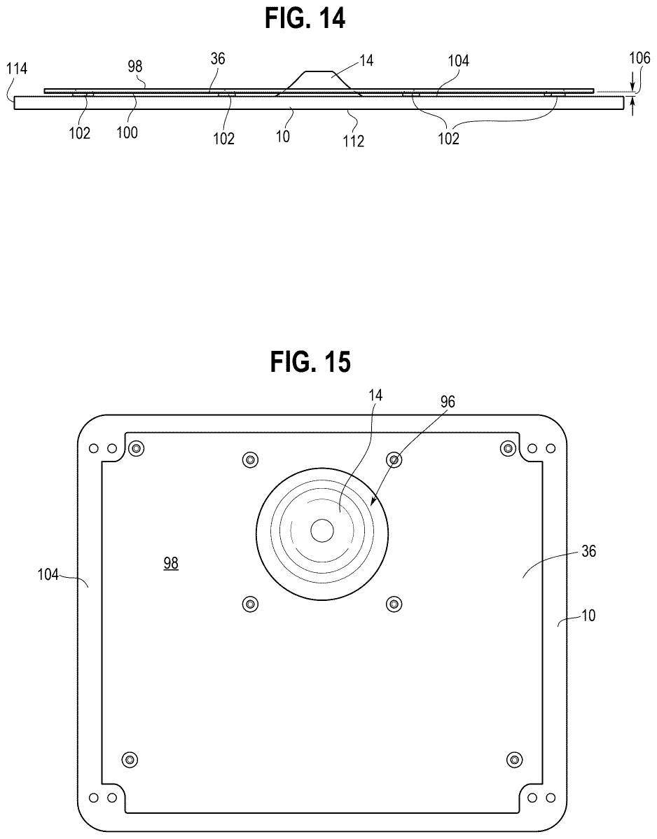

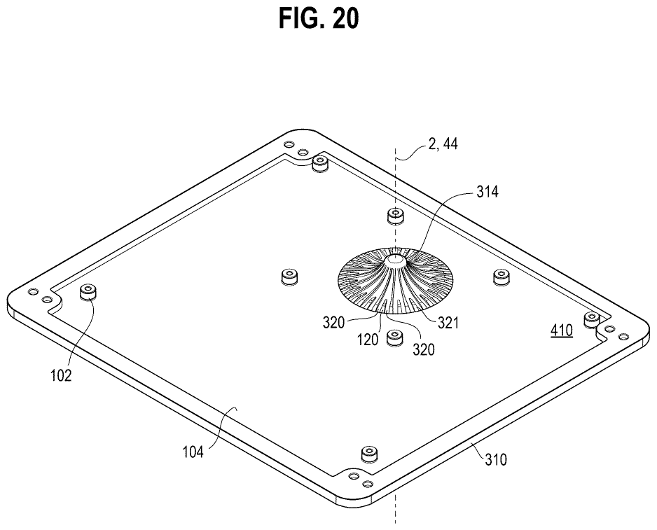

The base plate 10, 310 includes a planar base portion 110, 410 having opposite upper and lower sides 104, 112 and a peripheral edge 114. The base portion 110 may have a rectangular shape, and underlies the circuit board 36. The air guide 14, 314 extends orthogonally from upper side 104 of the base portion 110, 310 along the longitudinal axis 44. At least a portion of the air guide 14, 314 extends through the opening 96 in the circuit board 36 and through the outlet 48 in the heat sink 12, 312 and is disposed in the interior air flow passageway 42. The circuit board 36 overlies the base portion 110, 310, with the opening 96 aligned with, and receiving the air guide 14, 314, which is inserted through the opening 96. The air guide 14, 314 may have a rounded cone shape (convex or concave surface), or may be formed as a pyramid, a frusto-conical shape, or other geometric shape diminishing in cross-sectional area from a bottom to a top thereof. In one embodiment, the air guide 14, 314 has a plurality of laterally spaced air flow channels 120 formed on an upper surface/side thereof as shown in FIGS. 10-13 and 20. In other embodiments, the air guide 14 is smooth, and does not have any air flow channels, as shown for example in FIGS. 14 and 15. In one embodiment, the air flow channels 120 continue down the upper surface of the air guide and continue/extend as air flow channels 122 along the base portion 110, as shown for example in FIGS. 9 and 10. In other embodiments, shown for example in FIGS. 11-13 and 20, the channels 120 are terminated at the bottom of the air guide 14 and do not continue on the base portion 110, or extend under the circuit board 36. In the embodiment of FIG. 20, one or more of the channels 120 may be bifurcated at a bottom thereof by a rib 321 forming a pair of channels 320 diverging from the channel 120. The air flow channels 120, 122, 320 may be defined by raised ribs, or as recesses, formed on the upper surface of the air guide 14 and base portion 110. In the embodiments of FIGS. 8A-10, the air flow channels 122 may extend to the peripheral edges 114 of the base portion 110, wherein the air flow 80 may be exhausted to the ambient environment 30 through the exhaust vents 26 in the housing, formed in the sides, top or bottom of the housing. The flow channels 122 may be curvilinear, and may vary in width, for example having a greater width adjacent the periphery of the base plate than at the junction with the air guide 14. The flow channels 120 may match and flow into corresponding ones of the flow channels 122, with the channels 120, 122 forming a continuous flow channel from the top portion of the air guide 14 to the peripheral edge of the base portion 110.

The spacers 102 may be configured as mounting bosses extending orthogonally from the base portion 110 for mounting the circuit board 36 to the base plate 10. In this way, air flows 80 between the upper side 104 of the base portion 110 and the lower surface/side 100 of the circuit board 36 toward the peripheral edges 114 thereof. The air guide 14 may be offset relative to a center of, or not centered in the base portion 110 relative to the peripheral edges thereof. Correspondingly, the opening 96 may not be centered in the circuit board 36. In this way, the air flow 80 may be directed more immediately, and in greater amounts, toward one edge, or side of the housing, for example a rear thereof. The base plate 15 may be made as a casting, for example and without limitation, as an aluminum, zinc or composite material casting.

In operation, one exemplary method of dissipating heat from the plurality of heat producing electronic components 18 includes transferring heat from the plurality of heat producing electronic components 18 to the exterior surface 40 of the heat sink 12, 312, wherein the plurality of heat producing electronic components 18 are arranged in parallel relative to the longitudinal axis 44 of the heat sink 12, 312. The method further includes blowing air, or created an air flow 80, whether by positive or negative pressure, through the inlet 46 of the interior passageway 42 of the heat sink to the outlet 48, wherein the interior passageway 42 extends along the longitudinal axis 44 of the heat sink, directing the air flow 80 along the surface of the air guide 14, 314 extending through the outlet 48 into the interior passageway 42 and directing the air flow 80 laterally along the side/surface 104 of the base plate 10, 310, for example between the base portion 110, 410 and the circuit board 36, or beneath the circuit board 36, to the ambient environment 30. The side/surface 104 of the base plate is orthogonal to the longitudinal axis 44. Directing the air along the surface of the air guide includes flowing the air along the plurality of air flow channels 120, 122, 320 defined on the surface of the air guide and/or base portion. The air flow 80 is directed along the air guide 14, 314 through the opening 96 in the circuit board 36 to the upper surface of the base portion of the base plate, and beneath the circuit board 36, to the ambient environment.

Although the present invention has been described with reference to preferred embodiments, those skilled in the art will recognize that changes may be made in form and detail without departing from the spirit and scope of the invention. As such, it is intended that the foregoing detailed description be regarded as illustrative rather than limiting and that it is the appended claims, including all equivalents thereof, which are intended to define the scope of the invention.

What is claimed is:

1. A heat dissipation assembly comprising:
a heat sink comprising an exterior surface and an interior air flow passageway defining a longitudinal axis, wherein the air flow passageway comprises an inlet and an outlet;
a fan creating an air flow from the inlet to the outlet through the interior air flow passageway;
a plurality of laterally spaced heat producing electronic components abutting the exterior surface of the heat sink; and
a base plate comprising a base portion and an air guide extending orthogonally from the base portion along the longitudinal axis, wherein at least a portion of the air guide extends through the outlet and is disposed in the interior air flow passageway.

2. The heat dissipation assembly of claim 1 further comprising a circuit board disposed between the heat sink and the base plate, wherein the heat producing electronic components are coupled to the circuit board, and wherein the circuit board overlies the base portion of the base plate.

3. The heat dissipation assembly of claim 2 wherein the circuit board comprises an opening, wherein the air guide extends through the opening.

4. The heat dissipation assembly of claim 1 wherein the air guide comprises a plurality of laterally spaced air flow channels.

5. The heat dissipation assembly of claim 4 wherein the air flow channels extend along the base portion.

6. The heat dissipation assembly of claim 1 wherein the air guide has a rounded cone shape.

7. The heat dissipation assembly of claim 1 wherein the heat sink comprises a plurality of circumferentially spaced fins extending radially inwardly toward the longitudinal axis.

8. The heat dissipation assembly of claim 1 wherein the heat sink comprises at least four sides defining the exterior surface.

9. The heat dissipation assembly of claim 1 wherein the plurality of laterally spaced heat producing electronic components abutting the exterior surface of the heat sink are arranged in parallel around the longitudinal axis.

10. A base plate configured to guide air exiting a heat sink, the base plate comprising:
a planar base portion having a peripheral edge, a first side and an opposite second side; and
an air guide extending orthogonally from the first side of the base portion, wherein the air guide has a rounded cone shape surface.

11. The base plate of claim 10 wherein the air guide comprises a plurality of laterally spaced air flow channels on the rounded cone shape surface.

12. The base plate of claim 11 wherein the air flow channels extend from the air guide along the first side of the base portion.

13. The base plate of claim 10 wherein the base portion comprises a plurality of mounting bosses extending orthogonally from the first side of the base portion.

14. The base plate of claim 10 wherein the air guide is not centered in the base portion relative to the peripheral edge.

15. An amplifier comprising the dissipation assembly of claim 2, and further comprising a housing enclosing the fan, the heat sink and the base plate.

16. A method of dissipating heat from a plurality of heat producing electronic components comprising:
transferring heat from the plurality of heat producing electronic components to an exterior surface of a heat sink, wherein the plurality of heat producing electronic components are arranged in parallel relative to a longitudinal axis of the heat sink;
blowing air through an inlet of an interior passageway of the heat sink to an outlet, wherein the interior passageway extends along the longitudinal axis of the heat sink;
directing the air along a surface of an air guide extending through the outlet into the interior passageway; and
directing the air laterally along a surface of a base plate to an ambient environment.

17. The method of claim 16 wherein the surface of the base plate is orthogonal to the longitudinal axis.

18. The method of claim 16 wherein directing the air along the surface of the air guide comprises flowing the air along a plurality of air flow channels defined on the surface of the air guide.

19. The method of claim 16 wherein the air guide has a rounded cone shape.

20. The method of claim 16 wherein directing the air along the surface of the base plate comprises directing the air beneath a circuit board disposed between the base plate and the heat sink.

21. The method of claim 20 wherein directing the air along the surface of the air guide comprises directing the air through an opening defined in the circuit board to the surface of the base plate.
